(19) United States
(12) Patent Application Publication
(10) Pub. No.: US 2015/0066415 A1
(43) Pub. Date: Mar. 5, 2015

(54) Apparatus and Method for Measuring Microelectronic Electromagnetic Emissions to Detect Characteristics

(71) Applicant: United States of America as represented by the Secretary of the Navy, Crane, IN (US)

(72) Inventor: Brett Hamilton, Heltonville, IN (US)

(21) Appl. No.: 14/274,859

(22) Filed: May 12, 2014

Related U.S. Application Data
(60) Provisional application No. 61/821,965, filed on May 10, 2013.

(51) Int. Cl. G01R 31/28

(52) U.S. Cl. CPC G01R 31/2834
USPC 702/119

(57) ABSTRACT

A system and process can be adapted to determine if a device under test (DUT) is within predetermined acceptability or unacceptability pattern parameters based on configuration data and detectable emission or detectable signal profile data associated with a known good device under test (KGDUT). The system can include a sensor array which includes different electromagnetic or optical sensors that can include electrical and/or thermal sensors, a control section operable to position elements of the sensor array in proximity to different areas of interest of the KGDUT and DUT, a KGDUT/DUT control system operable to input a pattern of testing control signals adapted to generate the detectable emissions or detectable signal profile data from the KGDUT/DUT's areas of interest during KGDUT/DUT testing, an analysis system operable to compare the detectable emissions or detectable signal profile data from the KGDUT/DUT, and an input/output system operable to display results.

### CROSS-REFERENCE TO RELATED APPLICATIONS

The present application claims priority to U.S. Provisional Patent Application Ser. No. 61/821,965, filed May 10, 2013, entitled “APPARATUS AND METHOD FOR MEASURING MICROELECTRONIC ELECTROMAGNETIC EMISSIONS TO DETECT CHARACTERISTICS,” the disclosure of which is expressly incorporated by reference herein.

### STATEMENT REGARDING FEDERALLY SPONSORED RESEARCH OR DEVELOPMENT

The invention described herein was made in the performance of official duties by employees of the Department of the Navy and may be manufactured, used and licensed by or for the United States Government for any governmental purpose without payment of any royalties thereon. This invention (Navy Case 102,656) is assigned to the United States Government and is available for licensing for commercial purposes. Licensing and technical inquiries may be directed to the Technology Transfer Office, Naval Surface Warfare Center Crane, email: Cran_CTO@navy.mil.

### BACKGROUND AND SUMMARY OF THE INVENTION

The present invention relates to defect detection through detection of electromagnetic (EM) emission detection. One embodiment of the invention can use EM probes to measure EM emissions, e.g., EM interference (EMI), and to evaluate a device under test (DUT) system's operational EM characteristics. For example, an embodiment of the invention can incorporate integration of multiple EM probes in an array and in synchronization with DUT stimulation for the purpose of producing device unique EM signatures that can provide a novel approach to solving a variety of problems and meeting a variety of needs. An exemplary stimulus could be applied in such a way as to produce device dependent signatures useful in determining a probability that a device has a defect, improper part installed, or has otherwise experienced an environmental stress of interest. An exemplary EM apparatus in accordance with this disclosure may include a positioning system, switch matrix, power combiner, switch and EMI shielding to minimize stray EMI signals. An exemplary embodiment can also combine various EM probe types, such as E-field, and H-field probes of varying bandwidths, in an integrated manner.

Additional features and advantages of the present invention will become apparent to those skilled in the art upon consideration of the following detailed description of the illustrative embodiment exemplifying the best mode of carrying out the invention as presently perceived.

### BRIEF DESCRIPTION OF THE DRAWINGS

The detailed description of the drawings particularly refers to the accompanying figures in which:

FIG. 1 shows an exemplary schematic diagram of one aspect of one example embodiment of the invention; and

FIG. 2 shows an exemplary processing sequence in accordance with one embodiment of the invention.

### DETAILED DESCRIPTION OF THE DRAWINGS

The embodiments of the invention described herein are not intended to be exhaustive or to limit the invention to precise forms disclosed. Rather, the embodiments selected for description have been chosen to enable one skilled in the art to practice the invention.

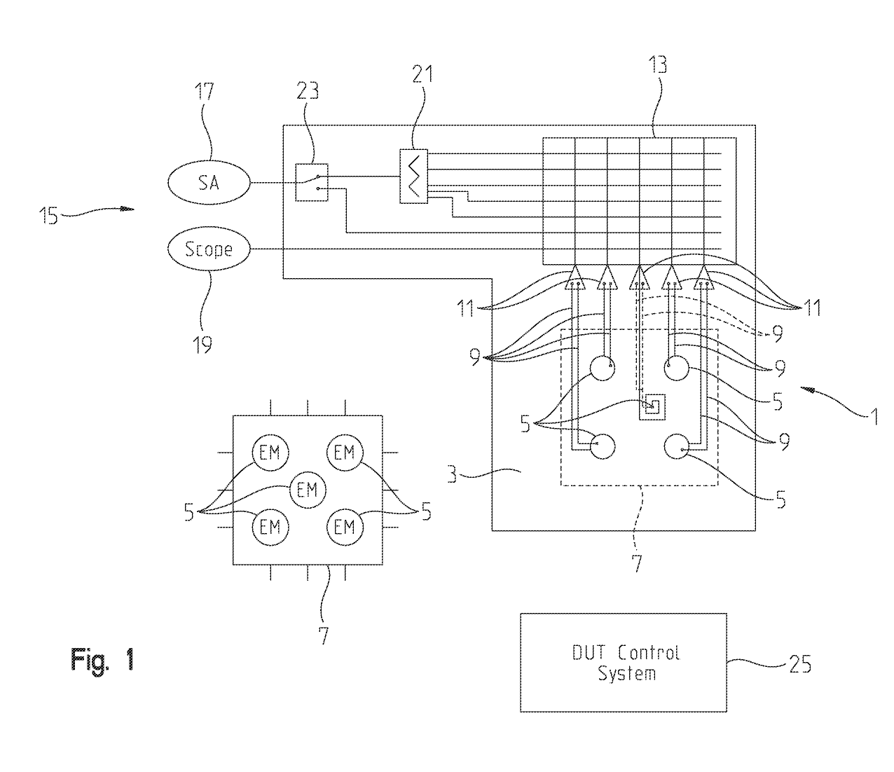

Referring initially to FIG. 1, an exemplary schematic diagram of one example embodiment of the invention is shown. An exemplary DUT testing assembly 1 is shown which includes a support fixture 3 which supports or positions EM sensors, e.g. EM probes, 5 in relation to a DUT 7. Signal paths 9 connect EM sensors 5 with amplifiers 11. Amplifiers 11 are coupled with a signal analysis section 15 which can provide signal analysis in a time domain and/or a frequency domain. For example, amplifiers 11 can be coupled with a signal analysis section 15 comprising a signal analyzer 17 and an oscilloscope 19 via a switch matrix 13. Separate connections (not shown) to the signal analysis section 15 can be used or a summing section 21 can be used which combines output from one or more amplifiers into a composite signal for input into the signal analysis section 15. A switch 23 can be interposed between the signal analysis section 15 and the summing section 21. The EM sensors 5 can be adapted to be repositionable or movable to be placed over specific areas of interest of a particular DUT 7.

One embodiment of the invention can include armatures (not shown) for use with an exemplary embodiment, e.g., a FIG. 1 system, to position an exemplary EM sensor 5 over areas of interest on a DUT 7. An exemplary embodiment can include servos that can include mechanisms to selectively move the EM sensors 5 over a DUT 7 for repeatable measurements to include multiple different identical DUTs 7 or multiple measurements including measurements in multiple positions relative to a DUT 7.

An exemplary embodiment of a DUT testing assembly 1 can include a multiplexer to permit selection of a single or any combination of EM sensors 5. A multiplexer can provide an ability to dynamically combine different EM sensors serving as array elements, minimizing signal acquisition time and quantity of data, while maintaining richness of signature information. A multiplexer adapted for use with one embodiment of the invention can also perform a function of a switch matrix 13 such as in FIG. 1.

A power combiner may be used to perform a function of a summing section 21. Such a power combiner would enable combination of signals selected by the multiplexer in a desirable manner e.g., to be combined in a manner maintaining 50 ohm impedance.

A plurality of EM sensors 5 can be formed into an array configuration to detect particular EM emissions such as a particular EM emission pattern from a particular set of components on a DUT 7 forming an EM signature pattern.

An embodiment of the invention can include multiple types of EM sensors. For example, the plurality of EM sensors 5 can include combinations of E-field and H-field sensors of various bandwidths. An embodiment of the invention using an array allows optimizing signal quality for a given technology and acquisition environment.

An embodiment of the invention can also include a DUT Control System 25 adapted to input a Known Good (KG) DUT Test Pattern Control Signals (KGDUTTPCS) (not shown) into a KG DUT 7 in order to stimulate the KG DUT 7 to produce signal characteristics to include a First EM Signature Profile (or KG EM Signature Profile (KGEMCSP)) for the KG DUT 7. At least one KGEMCSP is acquired by the array of EM Sensors 5 which can be positioned in a KG DUT EM Sensors Position (KGDUTEMSP). The KGEMCSP data and related KGDUTEMSP data are stored for later comparison with a second or subsequent DUTs having selected components, structure, and relationships that are the same or substantially similar to the first or KG DUT 7. The DUT Testing Assembly 1 in the same or other locations can later be configured to receive the subsequent or second DUT 7′, including components found in the first or KG DUT 7 having relatively the same or substantially similar physical/component/relational configurations. In particular, the same or a different EM Sensors 5 array in other locations can then be repositioned to substantially match the EM Sensors 5 array's pattern based on stored KGDUTEMSP associated with the First EM Signal Profile (or KGEMCSP) collected from the KG DUT 7.

In subsequent testing, the DUT Test Assembly 1 and DUT Control System 25 can stimulate the second or subsequent DUT 7′ (not shown) using the KGDUTTPCS associated with the KG DUT 7. The second or subsequent DUT 7′ then produces a Second EM Signature Profile or Under-Test (UT) EM Signature Profile (UTEMSP) which is then acquired by the EM sensors array 5 and stored as a second EM Signature Profile (or UTEMSP) data. The First and Second EM Signature Profiles (KGEMCSP and UTEMSP) are then compared and a determination of whether or not the second DUT 7′ is an acceptable DUT or unacceptable DUT; an acceptable DUT determination can be made where a substantial match between the First and Second EM Signature Profile indicates the Second DUT 7′ is a good DUT and a significant mismatch between the First and Second EM signal profile indicates the second DUT 7′ is a defective DUT.

The DUT Control System 25 can also include an ability to store KG DUT 7 configuration identification data and associated EM Signature Profiles for KG DUTs (e.g., DUT 7 configuration specifications and First EM and Configuration Signature Profile or KGEMCSP). The configuration specifications can be input by a user or detected by performing testing on said first DUT to determine, for example, operating parameters or specifications of said DUT to include voltage inputs, current, clock speed, or other detectable specifications of the KG DUT 7. Such DUT configuration identification data can also include non-specification detectable specification data e.g., optically or electrically detectable patterns, which can be associated with a KG DUT 7 and its stored KGEMCSP. EM Sensor array 5 configurations/positions and KGDUTTPC can be used to generate KG DUT's 7 First EM Signature Profile (or KGEMCSP).

An embodiment of the DUT Control System 25 can also be adapted to couple with the Signal Analysis Section 15 to receive outputs of the signal analysis section 15 and also to control EM sensor 5 positions and also to control devices or circuits positioned between EM sensors 5 and the Signal Analysis Section 15. An embodiment of the DUT Control System 25 can also include a storage medium adapted to store and output a plurality of machine readable instructions adapted to control various aspects of the invention including the DUT Control System 25 and DUT Testing Assembly 1 as well as providing for an output capability including a user interface.

An exemplary user interface can include a graphical user interface (GUI) (not shown) which can provide a graphical depiction of circuit behavior, EM Signature Profile comparison or overlays showing differences or no differences in detected EM signature profiles (e.g., comparison between the First and Second EM Signature Profiles (KGEMCSP and UTEMSP)) as well as a graphical indication of portions of the second or subsequent DUT 7′ which are producing a non-matching EM Signature. A user interface can also store data structures with selected test information to include EM Signature Profile Data (e.g., KGEMCSP and UTEMSP), mismatch data, and second or subsequent DUT 7′ identification.

The DUT Control System 25 can also include a plurality of machine implemented processing instructions stored on a digital recording media or other media such as a programmable logic structure to provide additional analytical processing such as a determination of probability of defects associated with a second or subsequent DUT 7′. A plurality of inputs can also be provided to the DUT Control System 25 to permit use of a wide variety of KGDUTTPCS and related KGDUTEMSP to generate KGEMCSPs or UTEMSPs to include power signatures, EM signatures, thermal signatures, specific electrical test inputs, initial settings on a second DUT 7′, electrostatic discharge (ESD), different input power or signal curves, pulse responses, or specific standard electrical tests. Additional sensors can be added to an embodiment of the invention to include thermal sensors which create a KG thermal sensor pattern which is then matched against a DUT 7′ thermal sensor output after application of one or more KGDUTTPCS and data collection via sensors positioned in the KGDUTEMSP. Image recognition software can be included in another embodiment of the invention to permit matching of thermal pictures or images of a KG DUT 7 with a second DUT 7′ to determine good or no-good DUT determinations.

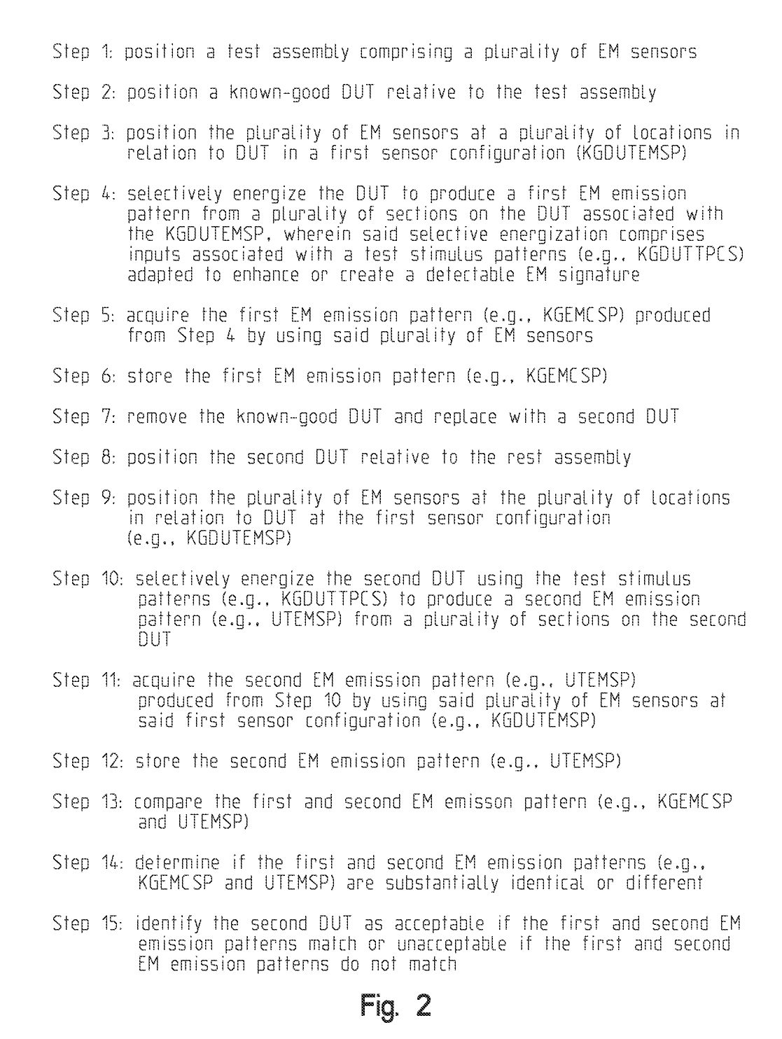

FIG. 2 shows an exemplary processing sequence in accordance with one embodiment of the invention. At Step 1: position a test assembly comprising a plurality of EM sensors; At Step 2: position a known-good DUT relative to the test assembly; At Step 3: position the plurality of EM sensors at a plurality of locations in relation to DUT in a first sensor configuration (KGDUTEMSP); At Step 4: selectively energize the DUT to produce a first EM emission pattern from a plurality of sections on the DUT associated with the KGDUTEMSP, wherein said selective energization comprises inputs associated with a test stimulus patterns (e.g., KGDUTTPCS) adapted to enhance or create a detectable EM signature; At Step 5: acquire the first EM emission pattern (e.g., KGEMCSP) produced from Step 4 by using said plurality of EM sensors; at Step 6: store the first EM emission pattern (e.g., KGEMCSP); At Step 7 remove the known-good DUT and replace with a second DUT; At Step 8: position the second DUT relative to the test assembly; At Step 9 position the plurality of EM sensors at the plurality of locations in relation to DUT at the first sensor configuration (e.g., KGDUTEMSP); At Step 10: selectively energize the second DUT using the test stimulus patterns (e.g., KGDUTTPCS) to produce a second EM emission pattern (e.g., UTEMSP) from a plurality of sections on the second DUT; At Step 11 acquire the second EM emission pattern (e.g., UTEMSP) produced from Step 10 by using said plurality of EM sensors at said first sensor configuration (e.g., KGDUTEMSP); At Step 12: store the second EM emission pattern (e.g., UTEMSP); At Step 13: compare the first and second EM emission pattern (e.g., KGEMCSP and UTEMSP); At Step 14: Determine if the first and second EM emission patterns (e.g., KGEMCSP and UTEMSP) are substantially identical or different; At Step 15: Identify the second DUT as acceptable if the first and second EM emission patterns match or unacceptable if the first and second EM emission patterns do not match.

One advantage of one embodiment of the invention includes providing an ability for users to implement an optimal design for a selected or target technology and permit rapid evaluation by creating a testing assembly, e.g., printed circuit board, with only sensor array elements, position of such elements and signal inputs for a control mechanism needing to be modified.

Although the invention has been described in detail with reference to certain preferred embodiments, variations and modifications exist within the spirit and scope of the invention as described and defined in the following claims.

1. A testing system adapted to determine if a device under test is within certain parameters used for determining acceptability or unacceptability based on configuration and testing profile data associated with a known good device under test:
a sensor array comprising a plurality of different sensors adapted to be moveable;
a signal analysis section comprising a section comprising a time domain and signal domain signal analysis signal section adapted to receive inputs from said plurality of different sensors;
a device under test (DUT) holder adapted to hold and position a first and second DUT relative to the sensor array;
a control mechanism adapted to independently position elements of said sensor array relative to areas of interest on said first and second DUT based on a first position input, wherein said first position input includes position control data operable to place said elements of said sensor array in proximity to said areas of interest, wherein each of said areas of interest generate one or more emissions or detectable signals which are detectable by one or more respective elements of said sensor array, said one or more emissions or detectable signals from said areas of interest comprise at least two or more different types of emissions;
a DUT control section adapted to stimulate said first DUT with a first plurality of test signal control inputs applied to said first DUT by said DUT control section, said DUT control section is further adapted to receive configuration data associated with said first DUT from either user input or configuration data collection from said sensor array based on a predetermined configuration testing sequence applied to said first DUT by said DUT control section, said DUT control section is further adapted to generate a first signature profile data comprising said configuration data associated with said first DUT and sensor array outputs from said respective elements of said sensor array associated with each of said areas of interest;
wherein said DUT control section is further adapted to stimulate said second DUT when said second DUT is placed in said DUT holder with said first plurality of test signal control inputs, said DUT control section is further adapted to acquire a second signature profile data associated with said sensor array outputs from said second DUT based on said first plurality of test signal control inputs to said second DUT and said first position input;
wherein said DUT control section is further adapted to match said first and second signature profile data, wherein a substantial match of said signature data indicates a first condition associated with said second DUT and a non-match indicates a second condition associated with said second DUT; and
an input and output section adapted to interact with said DUT control section, said input and output section comprising a user interface including a graphical user interface adapted to display an indication of said first or second condition associated with said second DUT.

2. A testing system as in claim 1, wherein said array comprising a plurality of different sensors comprises electromagnetic sensors.

3. A testing system as in claim 1, wherein said plurality of different sensors comprise a combination of E-field and H-field sensors of various bandwidths.

4. A testing system as in claim 1, wherein said first DUT comprises a known-good DUT.

5. A testing system as in claim 1, wherein said first and second signature profile data comprises electromagnetic signature profile data including data associated with different electromagnetic spectrum data, including electrical or optical data obtained from one or more of said plurality of different sensors of said sensor array.

6. A testing system as in claim 1, wherein said first condition is an acceptable condition and said second condition is an unacceptable condition.

7. A testing system as in claim 1, wherein said first and second signature profile data comprises detectable electromagnetic spectrum patterns associated with one or more said areas of interest.

8. A testing system as in claim 1, further comprising a storage medium adapted to store and output a plurality of machine readable instructions adapted to control various aspects of the testing system including the DUT Control System as well as control said input and output section to generate an output capability including a user interface.

9. A testing system as in claim 1, wherein said user interface comprises a graphical depiction of circuit behavior, said first and second signature profile data comparison or overlays showing differences or no differences in detected signature profile data, as well as a graphical indication of portions of the second DUT which are producing a non-matching signature profile data elements.

10. A testing system as in claim 1, wherein said input and output system further comprises a section operable to store data structures with selected test information comprising said first and second signature profile data, mismatch data associated with mismatches between said first and second signature profile data, and second DUT identification data.

11. A testing system as in claim 1, wherein said DUT control system further comprises a section comprising a plurality of processing sequences adapted to control said testing system or programmable logic structures adapted to provide additional analytical processing of said first and second signature profile data comprising a determination of probability of defects associated with said second or subsequent DUTs.

12. A testing system as in claim 1, wherein said first and second signature profile includes power signatures, electromagnetic signatures, thermal signatures, specific electrical test inputs associated with one or more said areas of interest, initial settings on a second DUT, electrostatic discharge (ESD) characteristics associated with one or more said areas of interest, different input power or signal curves associated with said first and second DUTs, pulse responses associated with said first and second DUTS, or specific standard electrical tests.

13. A testing system as in claim 1, wherein said sensor array comprises a thermal imager adapted to acquire a thermal picture or image of said first and second DUTs, wherein said first and second condition determination is further based on matching associated with thermal image picture of said first and second DUTs.

14. A method of testing a first and second device under tests comprising:
positioning a test assembly comprising a plurality of electromagnetic (EM) sensors;
positioning a known-good DUT relative to the test assembly;
positioning the plurality of EM sensors at a plurality of locations in relation to DUT in a first sensor configuration;
selectively energizing the DUT to produce a first EM emission or detectable signal pattern from a plurality of sections on the DUT associated with the first sensor configuration, wherein said selective energization comprises inputs associated with a plurality of test stimulus patterns adapted to enhance or create a detectable EM signature;
acquiring the first EM emission or detectable signal pattern using said plurality of EM sensors;
storing the first EM emission or detectable signal pattern;
positioning a second DUT relative to the test assembly;
positioning the plurality of EM sensors at the plurality of locations in relation to the second DUT at the first sensor configuration;
selectively energizing the second DUT using the test stimulus patterns to produce a second EM emission or detectable signal pattern from a plurality of sections on the second DUT;
acquiring the second EM emission or detectable signal patterns using said plurality of EM sensors at said first sensor configuration;
storing the second EM emission or detectable signal patterns;
comparing the first and second EM emission or detectable signal pattern and determining if the first and second EM emission or detectable signal patterns are within a range of values determined based on each element of said first EM emission or detectable signal patterns;
identifying the second DUT as acceptable if the second EM emission or detectable signal patterns are within said range of values determined based on each element of said first EM emission or detectable signal patterns; and
outputting a match or no-match data output based on said identification of said DUT as acceptable and either storing said match or no-match data in a recording medium or outputting said match or no-match data to a user interface.
